(19) United States
(12) Patent Application Publication
(10) Pub. No.: US 2015/0259792 A1
(43) Pub. Date: Sep. 17, 2015

(54) Method of Forming Titanium Carbonitride Film and Film Formation Apparatus Therefor

(71) Applicant: TOKYO ELECTRON LIMITED, Tokyo (JP)

(72) Inventors: Shigeru NAKAJIMA, Nirasaki City (JP); Hiromi SHIMA, Nirasaki City (JP); Yusuke TACHINO, Nirasaki City (JP)

(21) Appl. No.: 14/658,355

(22) Filed: Mar. 16, 2015

(30) Foreign Application Priority Data
Mar. 17, 2014 (JP) 2014-053453
Dec. 16, 2014 (JP) 2014-253789

(51) Int. Cl. C23C 16/34; C23C 16/50; C23C 16/455; C23C 16/08; C23C 16/52

(52) U.S. Cl. CPC C23C 16/347; C23C 16/08; C23C 16/52; C23C 16/455; C23C 16/50

(57) ABSTRACT

A method of forming a titanium carbonitride film is provided. In one embodiment, the method of forming the titanium carbonitride film includes performing a cycle a plurality of times to form a titanium carbonitride film. Each cycle performed a plurality of times includes supplying a raw material gas of titanium into a process chamber in which a process object is accommodated, and simultaneously supplying a first gas containing carbon and hydrogen and a second gas containing nitrogen into the process chamber.

### CROSS-REFERENCE TO RELATED APPLICATIONS

This application claims the benefit of Japanese Patent Applications No. 2014-053453, filed on Mar. 17, 2014, and No. 2014-253789, filed on Dec. 16, 2014, in the Japan Patent Office, the disclosures of which are incorporated herein in their entirety by reference.

### TECHNICAL FIELD

The present disclosure relates to a method of forming a titanium carbonitride film and a film formation apparatus therefor.

### BACKGROUND

As a material for films constituting electronic devices, titanium nitride is known in the art. A film composed of titanium nitride, that is, a titanium nitride film, is used as an electrode material constituting, for example, a capacitor of a dynamic random access memory (DRAM).

In addition, with increasing miniaturization of electronic devices, there is increasing demand for films having excellent quality for electronic devices. In light of such demand, a titanium carbonitride film is used instead of, for example, the titanium nitride film.

In a method of forming such a titanium carbonitride film, a cycle of sequentially supplying titanium tetrachloride (TiCl₄) gas, a carbon containing gas, and a nitrogen containing gas to a process chamber that accommodates a wafer is performed a plurality of times.

In the method of forming a titanium carbonitride film, the carbon containing gas and the nitrogen containing gas are sequentially supplied to the process chamber, that is, the carbon containing gas is supplied to the process chamber, followed by supply of the nitrogen containing gas to the process chamber. Thus, it is difficult to achieve an efficient increase in carbon concentration in the titanium carbonitride film within a predetermined number of cycles. Moreover, this method has difficulty in control of the concentration of carbon introduced into the titanium carbonitride film within a predetermined number of cycles.

### SUMMARY

Some embodiments of the present disclosure provide a method and apparatus, which form a titanium carbonitride film having high work function and high controllability of carbon concentration.

According to one embodiment of the present disclosure, there is provided a method of forming a titanium carbonitride film, including: performing a cycle a plurality of times to form a titanium carbonitride film, the cycle including: supplying a raw material gas of titanium into a process chamber in which a process object is accommodated, and simultaneously supplying a first gas containing carbon and hydrogen and a second gas containing nitrogen into the process chamber.

According to another embodiment of the present disclosure, there is provided a film formation apparatus including: a process chamber; a gas supply system supplying a raw material gas of titanium, a first gas containing carbon and hydrogen, and a second gas containing nitrogen into the process chamber; and a controller controlling the gas supply system, wherein the controller performs, a plurality of times, a control cycle for controlling the gas supply system to supply the raw material gas into the process chamber and controlling the gas supply system to simultaneously supply the first gas and the second gas into the process chamber.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a method of forming a titanium carbonitride film according to one embodiment of the present disclosure.

FIGS. 2A to 2C show views of one example of an object to be processed (hereinafter, referred to as a “process object”), showing states of the process object to which processes of the method shown in FIG. 1 are applied.

FIGS. 3A to 3E are diagrams illustrating a phenomenon when a first gas and a second gas are sequentially supplied, and a diagram illustrating a phenomenon when the first gas and the second gas are simultaneously supplied.

FIG. 4 is a flowchart illustrating a method of forming a titanium carbonitride film according to another embodiment of the present disclosure.

FIG. 5 is a schematic view of a film formation apparatus according to one embodiment of the present disclosure.

FIG. 6 is a cross-sectional view of the film formation apparatus shown in FIG. 5.

FIG. 7 is a schematic longitudinal sectional view of a film formation apparatus according to another embodiment of the present disclosure.

FIG. 8 is a perspective view of the film formation apparatus shown in FIG. 7, with a ceiling plate removed from the apparatus.

FIG. 9 is a horizontal cut-away plan view of the film formation apparatus shown in FIG. 7.

FIG. 10 is an enlarged perspective view of an activation gas injector.

FIG. 11 is a longitudinal sectional view of the activation gas injector shown in FIG. 10.

### DETAILED DESCRIPTION

Hereinafter, various embodiments of the present disclosure will be described with referenced to the accompanying drawings. Like components will be denoted by like reference numerals through the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

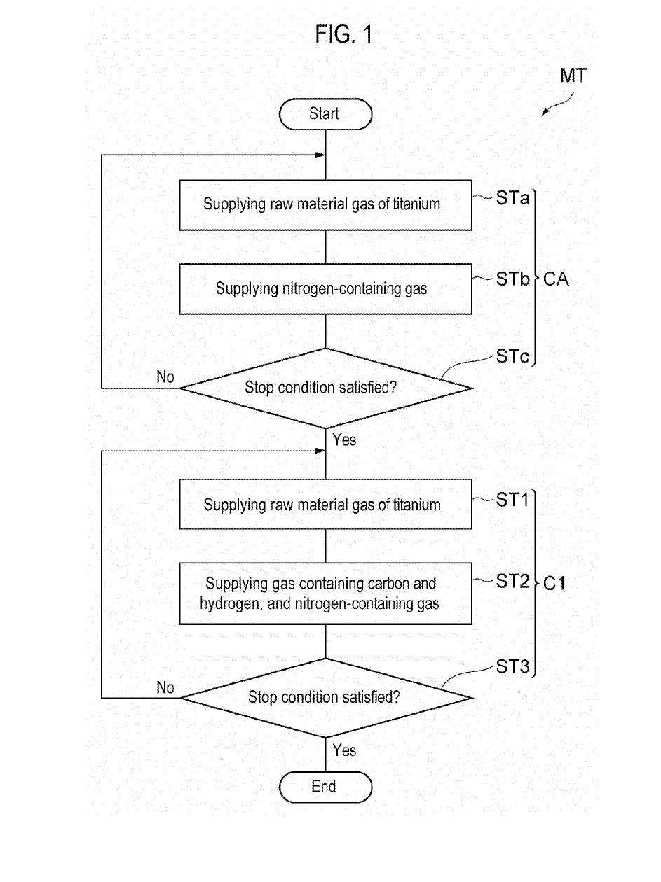

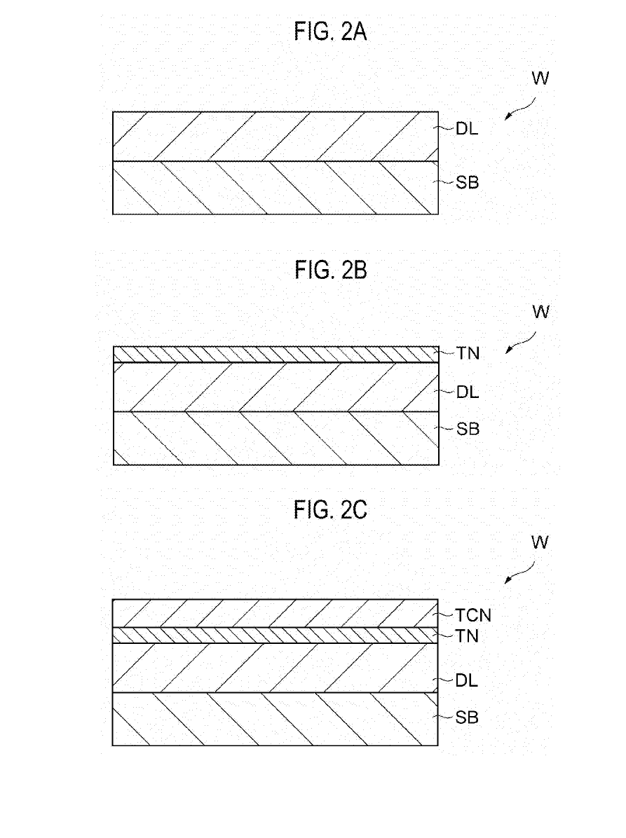

FIG. 1 is a flowchart illustrating a method of forming a titanium carbonitride film according to one embodiment of the present disclosure. In addition, FIGS. 2A to 2C show views of one example of an object to be processed (hereinafter, referred to as a “process object”), showing states of the process object to which processes of the method shown in FIG. 1 are applied. The method MT shown in FIG. 1 may be used to form a titanium carbonitride film on, for example, a process object, as shown in FIGS. 2A to 2C.

Referring to FIG. 2A, as an example of the process object, a wafer W includes a substrate SB and a dielectric layer DL. The dielectric layer DL is formed on the substrate SB and may be composed of, for example, zirconium oxide. Such film configuration of the wafer W may constitute, for example, part of a DRAM.

In the method MT according to one embodiment, a titanium nitride film TN is formed on the wafer W through cycle CA, as shown in FIG. 2B. Then, a titanium carbonitride film TCN is formed on the titanium nitride film TN through cycle C1, as shown in FIG. 2C. Further, in this method MT, the cycle CA is an optional cycle and becomes unnecessary in the case where only the titanium carbonitride film TCN is required. Further, the cycle CA may be performed after the cycle C1, as needed.

Next, referring to FIG. 1, the method MT will be described in more detail. In the method MT, the cycle CA includes a process STa and a process STb. In the process STa, a raw material gas of titanium is supplied into a process chamber that accommodates a wafer W. By performing the process STa, molecules constituting the raw material gas are adsorbed onto the wafer W. The raw material gas includes, for example, TiCl₄ gas.

Then, in the process STb, a nitrogen containing gas (third gas) is supplied into the process chamber. The third gas may be, for example, NH₃ gas or triethylamine. In the process STb, the third gas is decomposed to generate nitrogen. Also, in the process STa, chlorine is separated from the molecules adsorbed to the wafer W such that nitrogen is bonded to titanium. To this end, in the process sm, the gas supplied to the process chamber and the wafer W are heated. In the process STb, the gas and the wafer W are heated to a temperature in the range of, for example, 350 degrees C. to 450 degrees C. Alternatively, in the process STb, plasma of the third gas is generated.

In the cycle CA, the titanium nitride film TN may be formed through the process STa and the process sm, whereby the thickness of a stack layer including the titanium carbonitride film TCN formed by the cycle C1 described below and the titanium nitride film TN can be increased. The number of times that the cycle CA is performed may be set depending upon a desired film thickness, and may be once or more. When the cycle CA is performed once, the procedure of the method MT proceeds to the cycle C1 after performing the cycle CA once. On the other hand, when the cycle CA is performed a plurality of times, it is determined in the process STc whether stop conditions are satisfied. The stop conditions may be satisfied when the cycle CA is performed a predetermined number of times. If the stop conditions are not satisfied, the cycle CA is repeated again from the process STa. On the other hand, if the stop conditions are satisfied, the procedure of the method MT proceeds to the cycle C1.

The cycle C1 includes a process ST1 and a process ST2. The process ST1 of the cycle C1 is identical to the process STa. By the process ST1, molecules constituting a raw material gas of titanium are adsorbed onto the wafer W.

Then, in the process ST2, a first gas containing carbon and hydrogen, and a second gas containing nitrogen are supplied into the process chamber at the same time. The first gas may be, for example, hydrocarbon gas or triethylamine. More specifically, the first gas may include at least one selected from the group consisting of acetylene (C₂H₂) gas, ethylene (C₂H₄) gas, propylene (C₃H₆) gas, butadiene (C₄H₆) gas, triethylamine, and a mixture of two or more of the aforementioned gases. The second gas may be the same gas as the third gas, or may be, for example, NH₃ gas or triethylamine. In the process ST2, the first gas and the second gas are decomposed to generate carbon and nitrogen. Also, in the process ST1, chlorine is separated from the molecules adsorbed to the wafer W, such that carbon and nitrogen are bonded to titanium. To this end, in the process ST2, the gas supplied into the process chamber and the wafer W are heated. In the process ST2, the gas and the wafer W are heated to a temperature in the range of, for example, 350 degrees C. to 450 degrees C. Alternatively, in the process ST2, plasma of the first gas and the second gas is generated.

The cycle C1 including the processes ST1, ST2 is performed a plurality of times. Therefore, in the process ST3, it is determined whether stop conditions are satisfied. The stop conditions may be satisfied when the cycle C1 is performed a predetermined number of times. If the stop conditions are not satisfied, the cycle C1 is repeated again from the process ST1. On the other hand, if the stop conditions are satisfied, the process of the method MT is finished. In this manner, the titanium carbonitride film TCN is formed by repeating the cycle C1 a plurality of times.

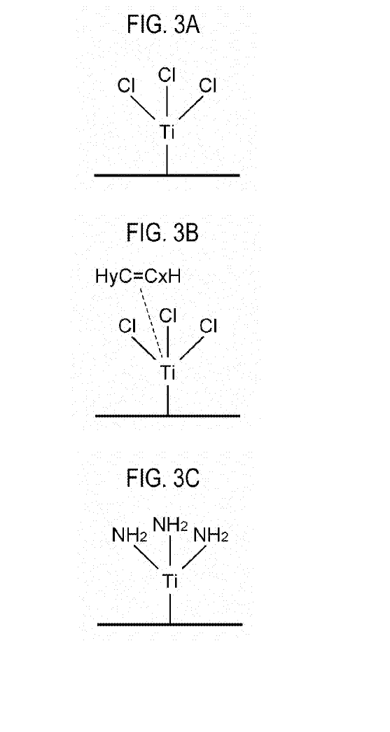

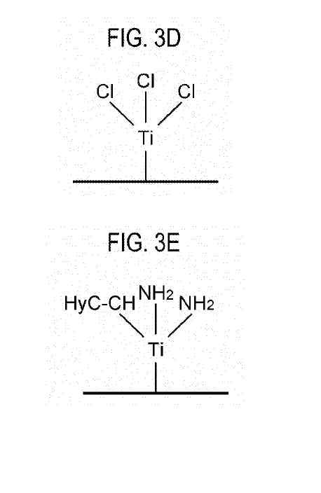

FIGS. 3A to 3E will be referred to here. FIGS. 3A to 3E are diagrams illustrating a phenomenon when the first gas and the second gas are sequentially supplied (see FIGS. 3A to 3C) and also a diagram illustrating a phenomenon when the first gas and the second gas are simultaneously supplied (see FIGS. 3D and 3E). As shown in FIG. 3A, when the raw material gas of titanium is supplied, molecules constituting the raw material gas of titanium are adsorbed onto the wafer W. Then, when the first gas is supplied alone, molecules (HyC═CxH) constituting the first gas are bonded to titanium (Ti), as shown in FIG. 3B. Next, when the second gas is supplied alone, bonds between the molecules constituting the first gas and titanium are severed by the molecules constituting the second gas. Thus, the molecules (NH₂) constituting the second gas are bonded to titanium, as shown in FIG. 3C. That is, when the first gas and the second gas are sequentially supplied, the concentration of carbon in the titanium carbonitride film is decreased.

On the other hand, in the process ST1 of the cycle C1 of the method MT, when the raw material gas of titanium is supplied, molecules constituting the raw material gas of titanium are adsorbed onto the wafer W, as shown in FIG. 3D. In addition, in the cycle C1 of the method MT, the first gas and the second gas are supplied to the process chamber at the same time in the process ST2. Thus, as shown in FIG. 3E, nitrogen (NH₂) may be bonded to titanium in the film formed by the process ST1, and carbon (HyC—CH) may be bonded thereto while suppressing to be substituted by nitrogen. Accordingly, it is possible to introduce a relatively large number of carbon atoms into the film within a limited number of cycles. Therefore, the cycle C1 enables supply of a titanium carbonitride film TCN having a high work function, whereby the titanium carbonitride film can have excellent controllability of carbon concentration.

Further, in the embodiment of the present disclosure, the cycle CA is performed before the cycle C1, as described above. By such cycle CA, the titanium nitride film TN can be formed between the dielectric layer DL and the titanium carbonitride film TCN. As a result, it becomes possible to suppress carbon diffusion from the titanium carbonitride film TCN to the dielectric layer DL.

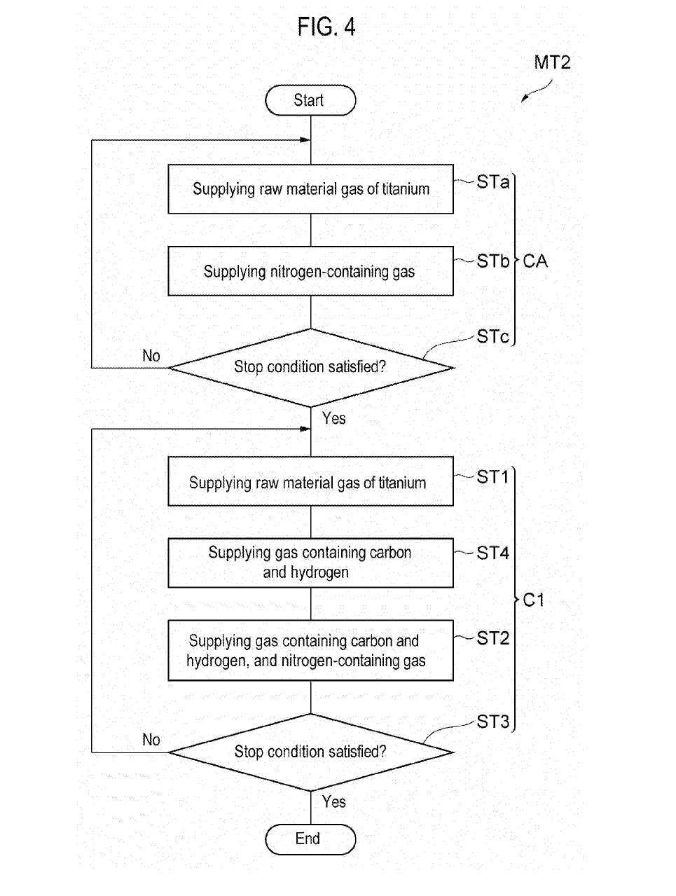

Next, a method of forming a titanium carbonitride film according to another embodiment of the present disclosure will be described. FIG. 4 is a flowchart illustrating a method of forming a titanium carbonitride film according to another embodiment of the present disclosure. The method MT2 shown in FIG. 4 is different from the method MT in that the cycle C1 includes a process ST4 between the processes ST1 and ST2. In the process ST4 of the method MT2, a gas containing carbon and hydrogen is supplied into the process chamber. The gas may be the same as the first gas. In the process ST4, the gas containing carbon and hydrogen and a wafer W are heated to a temperature in the range of, for example, 350 degrees C. to 450 degrees C. Alternatively, in the process ST4, plasma of the gas containing carbon and hydrogen may be generated. According to the method MT2, in the process ST4, carbon is bonded to titanium within the film formed in the process ST1, followed by performing the process ST3. Accordingly, it is possible to further increase the concentration of carbon in the titanium carbonitride film.

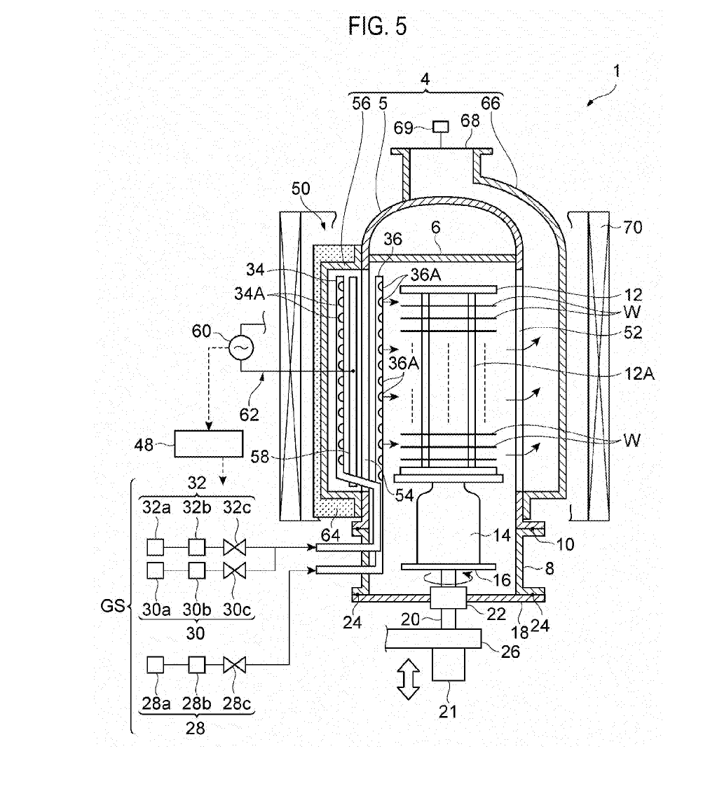

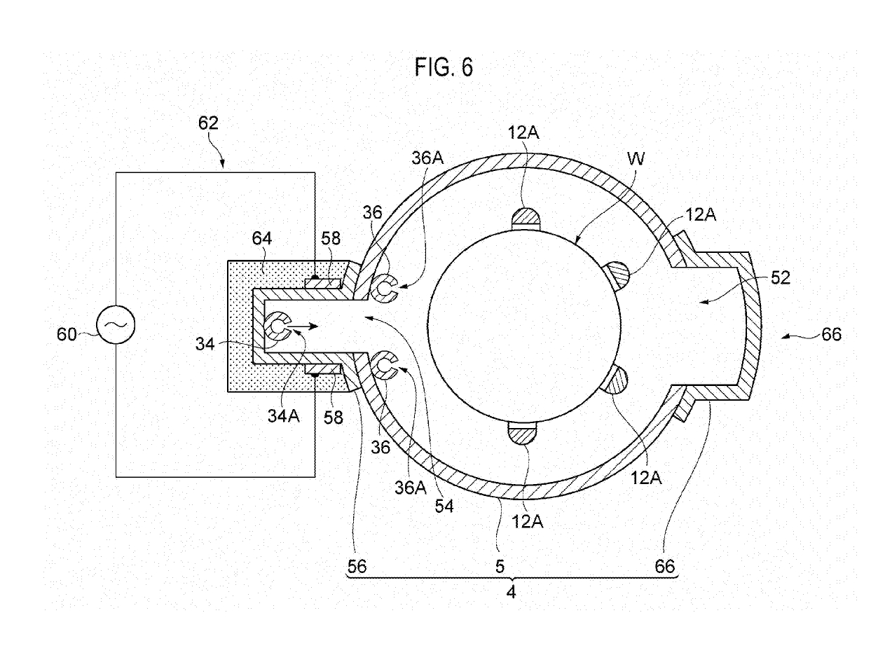

Next, some embodiments of a film formation apparatus applicable to the method MT and the method MT2 will be described. FIG. 5 is a schematic vertical sectional view of a film formation apparatus according to one embodiment of the present disclosure. FIG. 6 is a cross-sectional view of the film formation apparatus shown in FIG. 5.

Referring to FIGS. 5 and 6, a film formation apparatus 1 includes a process chamber 4. The process chamber 4 includes a main body 5, a partition wall 56, and a cover member 66. The main body 5 has a substantially cylindrical shape, and is open at a lower end thereof and closed at an upper end thereof. The main body 5 is formed of, for example, quartz. The main body 5 is provided at the upper end thereof with a ceiling plate 6 made of quartz. Further, a manifold 8 is connected to an opening at the lower end of the main body 5, through a sealing member 10 such as an O-ring. The manifold 8 is formed of, for example, stainless steel, and may have a substantially cylindrical shape.

The process chamber 4 is provided therein with a wafer boat 12. The wafer boat 12 is configured to support a plurality of wafers W. In one example, the wafer boat 12 includes posts 12A. The posts 12A are configured to support the plurality of wafers W at a predetermined pitch in multiple layers.

The wafer boat 12 is loaded on a table 16, with a heat insulating container 14 made of quartz disposed therebetween. The table 16 is supported by a rotational shaft 20. The rotational shaft 20 passes through a lid 18 in the perpendicular direction. The lid 18 closes the opening of the manifold 8 at the lower end of the manifold 8. For example, a magnetic fluid seal 22 is disposed between the rotational shaft 20 and the lid 18. Further, a seal member 24 such as an O-ring is disposed between the periphery of the lid 18 and the lower end of the manifold 8.

The rotational shaft 20 is coupled to a drive device 21 disposed at a leading end of an arm 26. The drive device 21 is configured to rotate the rotational shaft 20. Further, the arm 26 is supported by, for example, a lift mechanism such as a boat elevator and the like. With this structure, the wafer boat 12, the lid 18 and the like can be integrally raised or lowered to insert the wafer boat 12 into the process chamber 4, or to withdraw the wafer boat 12 from the process chamber 4.

In addition, the film formation apparatus 1 further includes a gas supply system GS. The gas supply system GS includes a gas supply unit 28, a gas supply unit 30, and a gas supply unit 32. The gas supply unit 28 supplies a raw material gas of titanium into the process chamber 4. The gas supply unit 28 includes a gas source 28a, a flow rate controller 28b, and a shut-off valve 28c. The gas source 28a is a source of the raw material gas of titanium, for example, TiCl₄ gas. The flow rate controller 28b is a flow rate control device such as a mass flow controller and serves to adjust the flow rate of the raw material gas. The shut-off valve 28c serves to permit or block supply of the raw material gas. The flow rate controller 28b and the shut-off valve 28c are controlled by a controller 48. The gas source 28a is connected to a gas spray nozzle 36 through the flow rate controller 28b and the shut-off valve 28c. In one embodiment, the gas supply system is provided with two gas spray nozzles 36. The gas spray nozzle 36 perpendicularly extends into an interior space of the main body 5 through the manifold 8. The gas spray nozzle 36 extending into the main body 5 is formed with a plurality of gas spray orifices 36A. With such a gas supply unit 28, the raw material gas can be supplied into the process chamber 4 at an adjusted flow rate. Further, supply of the raw material gas into the process chamber 4 can be controlled.

The gas supply unit 30 supplies a first gas, that is, a gas containing carbon and hydrogen, into the process chamber 4. The gas supply unit 30 includes a gas source 30a, a flow rate controller 30b, and a shut-off valve 30c. The gas source 30a is a source of the first gas. The flow rate controller 30b is a flow rate control device such as a mass flow controller and serves to adjust the flow rate of the first gas. The shut-off valve 30c serves to permit or block supply of the first gas. The flow rate controller 30b and the shut-off valve 30c are controlled by the controller 48. The gas source 30a is connected to a gas spray nozzle through the flow rate controller 30b and the shut-off valve 30c. The gas spray nozzle 34 perpendicularly extends into the main body 5 through the manifold 8, and also perpendicularly extends in a space 54 provided by the partition wall 56. The gas spray nozzle 34 is formed with a plurality of gas spray orifices 34A. With such a gas supply unit 30, the first gas can be supplied into the process chamber 4 at an adjusted flow rate. Further, supply of the first gas into the process chamber 4 can be controlled.

The gas supply unit 32 supplies a nitrogen-containing gas, for example, NH₃ gas or trimethylamine, which will be commonly used as the second gas and the third gas, into the process chamber 4. The gas supply unit 32 includes a gas source 32a, a flow rate controller 32b, and a shut-off valve 32c. The gas source 32a is a source of the nitrogen-containing gas. The flow rate controller 32b is a flow rate control device such as a mass flow controller and serves to adjust the flow rate of the nitrogen-containing gas. The shut-off valve 32c serves to permit or block supply of the nitrogen-containing gas. The flow rate controller 32b and the shut-off valve 32c are controlled by the controller 48. The gas source 32a is connected to a gas spray nozzle 34 through the flow rate controller 32b and the shut-off valve 32c. With such a gas supply unit 32, the nitrogen-containing gas can be supplied into the process chamber 4 at an adjusted flow rate. Further, supply of the nitrogen-containing gas into the process chamber 4 can be controlled.

The partition wall 56 of the process chamber 4 is a wall that provides the space 54 extending in the perpendicular direction and having a substantially rectangular cross-section. Also, the partition wall 56 is coupled to the main body 5 such that the space 54 is in communication with the interior space of the main body 5. The gas spray nozzle 34 perpendicularly extends within the space 54 provided by the partition wall 56.

The film formation apparatus 1 further includes a plasma generator 50 that excites the gas supplied through the gas spray nozzle 34. The plasma generator 50 includes a pair of electrodes 58 and an RF power source 60. The pair of electrodes 58 is attached to a pair of sidewalls of the partition wall 56, with the space 54 interposed therebetween. Further, the pair of electrodes 58 extends in the perpendicular direction. The RF power source 60 is connected to the pair of electrodes 58 via a power supply line 62. The RF power source 60 supplies RF power having a frequency of, for example, 13.56 MHz, to the pair of electrodes 58. The RF power supplied from the RF power source 60 creates an RF electric field in the space 54, in which the gas supplied from the gas spray nozzle 34 is excited. Then, the excited gas, that is, plasma, spreads in the interior space of the main body 5.

Furthermore, the film formation apparatus 1 is provided with an insulation protective cover 64 that covers the partition wall 56. The insulation protective cover 64 is made of, for example, quartz. The insulation protective cover 64 may have a coolant passage provided therein or may be configured to supply a coolant through the coolant passage such that the electrodes 58 can be cooled thereby.

The cover member 66 of the process chamber 4 is coupled to the main body 5. The cover member 66 provides an exhaust port 52 disposed to face the space 54, with the interior space of the main body 5 interposed between the exhaust port 52 and the space 54. Further, the cover member 66 extends upwards along the main body 5 and provides a gas outlet 68 at an upper portion of the main body 5. The gas outlet 68 is connected to an exhaust device 69, such as a vacuum pump.

The film formation apparatus 1 further includes a heater 70. The heater 70 has a substantially cylindrical shape and is disposed to surround the outer circumference of the process chamber 4. The heater 70 heats the gas introduced into the process chamber 4 and wafers W.

Further, the controller 48 may control the RF power source 60 and the heater 70 in addition to the respective components of the gas supply system GS. The controller 48 may be a computer device, which includes a memory device such as a recipe memory, an input device configured to receive operator input, a processor such as a central processing unit (CPU), and an interface configured to send a control signal. When the method MT is performed by the film formation apparatus 1, the controller 48 performs control operation as described hereinafter.

The controller 48 performs a control cycle, i.e., a second control cycle, at least once in order to perform the cycle CA of the methods MT and MT2 at least once. In each second control cycle, the controller 48 controls the flow rate controller 28b and the shut-off valve 28c of the gas supply unit 28 such that a raw material gas of titanium is supplied from the gas source 28a into the process chamber 4. As a result, the process STa of the cycle CA is performed. Then, in each second control cycle, the controller 48 controls the flow rate controller 32b and the shut-off valve 32c of the gas supply unit 32 such that a nitrogen-containing gas is supplied from the gas source 32a into the process chamber 4. As a result, the process STb of the cycle CA is performed. In the process STb, the controller 48 may control the plasma generator 50 to generate plasma of the nitrogen-containing gas. In this case, the controller 48 controls the RF power source 60 to supply RF power to the pair of electrodes 58. Alternatively, in the process ST2, the controller 48 may control the heater 70 such that heat energy is supplied to the heater 70.

Further, the controller 48 performs a control cycle, i.e., a first control cycle, a plurality of times, in order to perform the cycle C1 of the methods MT and MT2 a plurality of times. In each first control cycle, the controller 48 controls the flow rate controller 28b and the shut-off valve 28c of the gas supply unit 28 such that the raw material gas of titanium is supplied from the gas source 28a into the process chamber 4. As a result, the process ST1 of the cycle C1 is performed. Next, in the method MT2, the controller 48 controls the flow rate controller 30b and the shut-off valve 30c of the gas supply unit 30 such that the first gas is supplied from the gas source 30a into the process chamber 4. As a result, the process ST4 of the cycle C1 is performed. Further, in order to perform the process ST2 subsequent to the process ST1 in the method MT, and in order to perform the process ST2 subsequent to the process ST4 in the method MT2, the controller 48 controls the flow rate controller 30b and the shut-off valve 30c of the gas supply unit 30 such that the first gas is supplied from the gas source 30a into the process chamber 4. At the same time, the controller 48 controls the flow rate controller 32b and the shut-off valve 32c of the gas supply unit 32 such that the nitrogen-containing gas is supplied from the gas source 32a into the process chamber 4. As a result, the process ST2 of the cycle C1 is performed. Further, in the process ST2, the controller 48 may control the plasma generator 50 to generate plasma of the first gas and the nitrogen-containing gas. In this case, the controller 48 controls the RF power source 60 to supply RF power to the pair of electrodes 58. Alternatively, in the process ST2, the controller 48 may control the heater 70 such that heat energy is supplied to the heater 70.

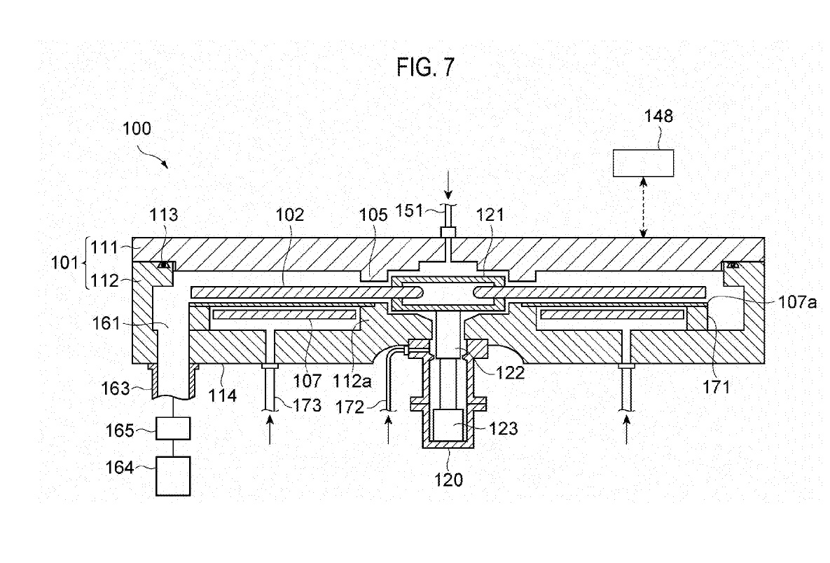

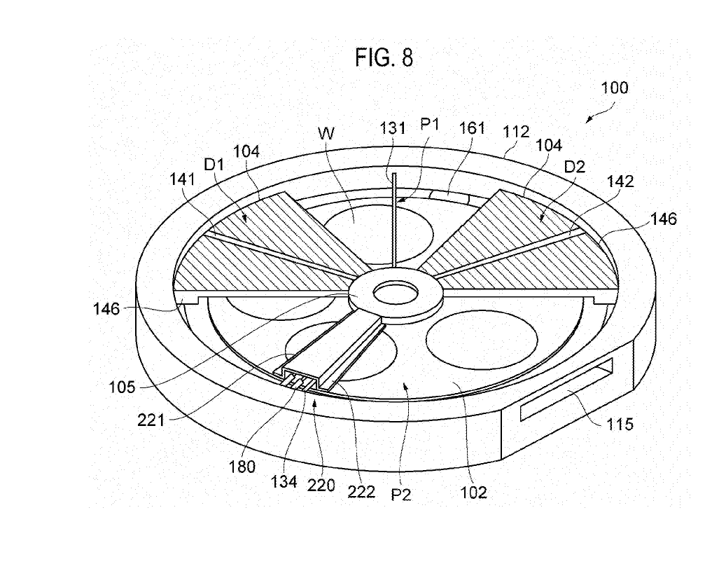

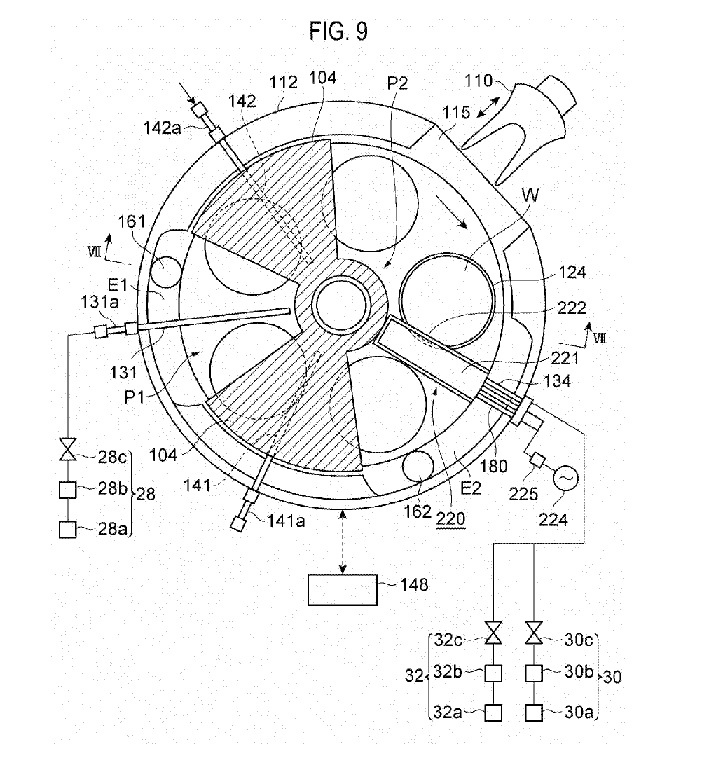

Next, a film formation apparatus according to another embodiment of the present disclosure applicable to the method MT will be described. FIG. 7 is a schematic longitudinal sectional view of a film formation apparatus according to another embodiment of the present disclosure. FIG. 8 is a perspective view of the film formation apparatus shown in FIG. 7, with a ceiling plate removed from the apparatus. FIG. 9 is a partially cut-away plan view of the film formation apparatus shown in FIG. 7. Here, FIG. 7 shows a cross-section of the film formation apparatus taken along a line VII-VII of FIG. 9.

Referring to FIGS. 7 to 9, the film formation apparatus 100 includes a process chamber 101. The process chamber 101 has a substantially disc-shaped interior space therein. The interior space of the process chamber 101 provides a region P1, a divided region D1, a region P2, and a divided region D2 arranged in a circumferential direction with respect to a central axis described below. The process chamber 101 includes a ceiling plate 111 and a main body 112. The main body 112 has a substantially cylindrical shape and constitutes a sidewall and a bottom of the process chamber 101. The main body 112 is formed at the sidewall thereof with a transfer port 115. A wafer W held by a transfer arm 110 is brought in and out through the transfer port 115. In addition, the transfer port 115 can be opened or closed by a gate valve.

The ceiling plate 111 constitutes the ceiling of the process chamber 101. The ceiling plate 111 is placed on an upper end of the main body 112, and an O-ring 113 is disposed between the ceiling plate 111 and the main body 112. The O-ring 113 secures sealing between the ceiling plate 111 and the main body 112.

The process chamber 101 is provided therein with a rotational table 102. The rotational table 102 has a substantially disc shape. The rotational table 102 is secured at a center thereof to a cylindrical core 121. The core 121 is secured to an upper end of a rotational shaft 122. The rotational shaft 122 extends in the vertical direction and passes through a bottom 114 of the main body 112 of the process chamber 101. The rotational shaft 122 is connected at a lower end thereof to a drive unit 123. The drive unit 123 rotates the rotational shaft 122 about a rotational axis thereof. The rotational shaft 122 and the drive unit 123 are accommodated in a cylindrical case 120. The case 120 is air-tightly coupled to the bottom 114.

As shown in FIGS. 8 and 9, the rotational table 102 is formed at an upper side thereof with five depressions 124 on which wafers W will be loaded. The depressions 124 are arranged in the circumferential direction with respect to the rotational axis of the rotational table 102, that is, the central axis of the rotational table 102. Each of the depressions 124 has a slightly greater diameter than the wafer W and has a depth that is substantially the same as the thickness of the wafer W.

As shown in FIGS. 8 and 9, above the rotational table 102, a gas nozzle 131, two dividing gas nozzles 141, 142, and an activation gas injector 220 are provided. The gas nozzle 131, the two dividing gas nozzles 141, 142, and the activation gas injector 220 are disposed to face the upper side of the rotational table 102, arranged in the circumferential direction, and extended in the radial direction.

The gas nozzle 131 is provided at the region P1 and the activation gas injector 220 is provided at the region P2. The dividing gas nozzle 141 is disposed above the divided region D1 between the region P2 and the region P1. Further, the dividing gas nozzle 142 is disposed above the divided region D2 between the region P1 and the region P2.

The gas nozzle 131 is formed with a plurality of downward facing gas ejection orifices. These gas ejection orifices are arranged in the radial direction such that a gas can be evenly sprayed onto the wafer W. The gas nozzle 131 is formed at a proximal end thereof with a gas inflow port 131a. The gas inflow port 131a is formed outside the process chamber 101. The gas supply unit 28 is connected to the gas inflow port 131a. Like the gas supply unit 28 of the film formation apparatus 1, the gas supply unit 28 is a gas supply device. In the film formation apparatus 100, the gas supply unit 28 and the gas nozzle 131 constitute part of a gas supply system according to one embodiment of the present disclosure. In this gas supply system, the wafer W will be exposed to a raw material gas of titanium in the region P1.

Further, each of the dividing gas nozzles 141, 142 is formed with a plurality of downward facing gas ejection orifices. The dividing gas nozzles 141, 142 are formed at proximal ends thereof with gas inflow ports 141a, 142a, respectively. Both the gas inflow ports 141a, 142a are formed outside the process chamber 101. A source of a dividing gas is connected to each of the gas inflow ports 141 a, 142a through the flow rate controller and the shut-off valve, respectively. The dividing gas is a gas for dividing the region P1 and the region P2 to prevent the raw material gas supplied to the region P1 and the gas (or activation gas) supplied from the activation gas injector 220 to the region P2 from mixing with each other. Also, the dividing gas may be an inert gas. The inert gas may be, for example, N₂ gas or noble gas.

The divided region D1 and the divided region D2 are partitioned from above by protruding features 104 of the ceiling plate 111. The protruding features 104 protrude downwards below a plane of a space within the process chamber 101 of the ceiling plate 111 extending around the protruding features 104 in the circumferential direction. In addition, the protruding features 104 have a substantially fan-like planar shape. Further, each of the protruding features 104 is formed with a groove extending in the radial direction, and the dividing gas nozzles 141, 142 are received in the grooves.

Further, the ceiling plate 111 provides a protrusion 105, which faces an outer circumferential surface of the core 121. Further, an outer section of the protruding feature 104 in the radial direction provides a round section 146, which is rounded to face an outer circumferential surface of the rotational table 102. The protrusion 105 and the round sections 146 further improve performance of dividing the gas supplied to the region P1 and the gas (or activation gas) supplied to the region P2.

In addition, the interior space of the process chamber 101 provides an exhaust region E1 and an exhaust region E2 outside the region P1 and the region P2 in the radial direction, respectively. An exhaust port 161 is formed in the bottom 114 under the exhaust region E1. Further, an exhaust port 162 is formed in the bottom 114 under the exhaust region E2. The exhaust ports 161, 162 are connected to an exhaust device 164 such as a vacuum pump via an exhaust pipe 163 and a pressure regulator 165.

Further, a heater unit 107 is disposed in a space between the rotational table 102 and the bottom 114. The heater unit 107 is placed within a space surrounded by cover sections 107a, 171, and 112a. The cover section 107a is placed above the heater unit 107 to cover the heater unit 107. The cover section 171 is placed outside the heater unit 107 in the radial direction to cover the heater unit 107. Further, the cover section 112a is placed inside the heater unit 107 in the radial direction to cover the heater unit 107. A purge gas (for example, N₂ gas) is supplied to the space surrounded by the cover sections 107a, 171, and 112a through a pipe 173. Further, the purge gas is also supplied to a space between the cover section 112a and the core 121 through the pipe 172. Further, the ceiling plate 111 is connected at the center thereof to the pipe 151, and the dividing gas is also supplied to a space between the core 121 and the ceiling plate 111.

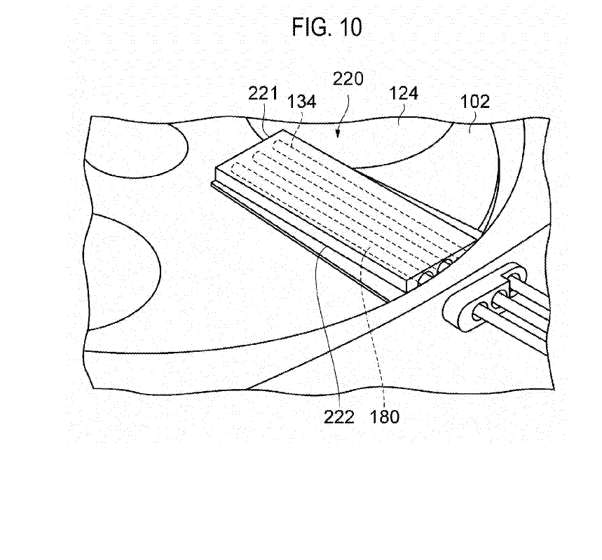

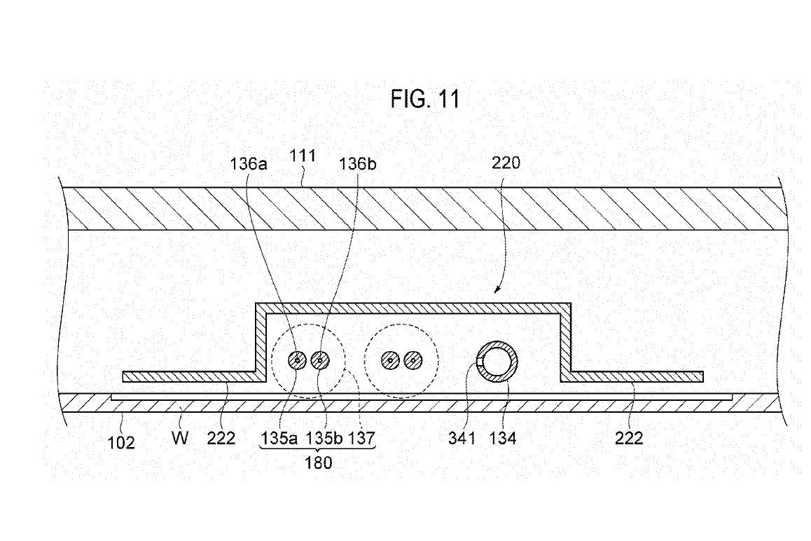

Next, the activation gas injector 220 will be described. FIG. 10 is an enlarged perspective view of the activation gas injector. FIG. 11 is a longitudinal sectional view of the activation gas injector shown in FIG. 10. As described above, the activation gas injector 220 is placed in the region P2. The activation gas injector 220 includes a gas nozzle 134. The gas nozzle 134 extends from a sidewall of the process chamber 101 toward the center of the interior space of the process chamber 101. The gas nozzle 134 is formed with a plurality of gas ejection orifices 341. The gas nozzle 134 is connected to the gas supply unit 30 and the gas supply unit 32. The aforementioned gas supply units 30, 32 are similar to the gas supply units 30, 32 of the film formation apparatus 1. In the film formation apparatus 100, the gas nozzle 134, the gas supply unit 30, and the gas supply unit 32 constitute part of the gas supply system according to the embodiment of the present disclosure.

In addition, the activation gas injector 220 includes an activation unit 180. The activation unit 180 includes a sheath tube 135a and a sheath tube 135b. Each of the sheath tubes 135a, 135b is covered with a protective tube 137. The sheath tubes 135a, 135b are arranged parallel to each other and extend from the sidewall of the process chamber 101 towards the center of the interior space of the process chamber 101. The sheath tubes 135a, 135b are made of a dielectric material, such as quartz, alumina, and yttria. The sheath tubes 135a, 135b have electrodes 136a, 136b inserted therein, respectively. The electrodes 136a, 136b constitute parallel electrodes. The electrodes 136a, 136b are connected to an RF power source 224 through a rectifier 225. The RF power source 224 supplies RF power having a frequency of, for example, 13.56 MHz, to the electrodes 136a, 136b. When RF power is supplied to the electrodes 136a, 136b, an RF electric field is generated around the activation unit 180. The first gas and/or the nitrogen-containing gas are excited by the RF electric field. Accordingly, in the film formation apparatus 100, the activation unit 180, the rectifier 225, and the RF power source 224 constitute a plasma generation system according to one embodiment of the present disclosure.

Further, the activation gas injector 220 includes a cover body 221. The cover body 221 is made of a dielectric material, for example, quartz. The cover body 221 covers the gas nozzle 134, the sheath tubes 135a, 135b from upper and lateral sides thereof. In addition, the activation gas injector 220 is provided with restricting planes 222 being continuous along both lower sides of the cover body 221 in the circumferential direction thereof. The restricting planes 222 extend from both lower sides of the cover body 221 in the circumferential direction thereof.

By such an activation gas injector 220, the nitrogen-containing gas supplied from the gas nozzle 134, or a mixture of the nitrogen-containing gas and the first gas is excited by the RF electric field generated by RF power. Accordingly, in the region P2, the wafer W will be exposed to plasma of the nitrogen-containing gas and/or plasma of the first gas.

The film formation apparatus 100 further includes a controller 148. The controller 148 may be a computer device, which includes a memory device such as a recipe memory, an input device configured to receive an operator input, a processor such as a CPU, and an interface configured to send a control signal. When the method MT is performed by the film formation apparatus 1, the controller 148 performs a control operation as described hereinafter.

The controller 148 performs, at least once, a second control cycle to perform the cycle CA of the method MT at least once. In each second control cycle, the controller 148 operates the drive unit 123 to rotate the rotational table 102. When the film formation apparatus 100 is used, one revolution of the wafer W about the central axis of the process chamber 101 in the interior space of the process chamber 101 corresponds to a single second control cycle. In each second control cycle, the controller 148 controls the flow rate controller 28b and the shut-off valve 28c of the gas supply unit 28 such that a raw material gas of titanium is supplied from the gas source 28a to the region P1. As a result, the process STa of the cycle CA is performed while the wafer W passes through the region P1. Further, in each second control cycle, the controller 148 controls the flow rate controller 32b and the shut-off valve 32c of the gas supply unit 32 such that a nitrogen-containing gas is supplied from the gas source 32a. Also, the controller 148 controls the RF power source 224 of the plasma generation system to generate plasma of the nitrogen-containing gas. As a result, the process STb of the cycle CA is performed while the wafer W passes through the region P2. Alternatively, in the process STb, the controller 148 may control the heater unit 107 such that heat energy is supplied to the heater unit 107, instead of controlling plasma generation.

Further, the controller 148 performs, a plurality of times, a first control cycle to perform the cycle C1 of the method MT a plurality of times. In each first control cycle, the controller 148 operates the drive unit 123 to rotate the rotational table 102. When the film formation apparatus 100 is used, one revolution of the wafer W about the central axis of the process chamber 101 in the interior space of the process chamber 101 corresponds to a single first control cycle. In each first control cycle, the controller 148 controls the flow rate controller 28b and the shut-off valve 28c of the gas supply unit 28 such that a raw material gas of titanium is supplied from the gas source 28a to the region P1. As a result, the process ST1 of the cycle C1 is performed while the wafer W passes through the region P1. Further, in each first control cycle, the controller 148 controls the flow rate controller 30b and the shut-off valve 30c of the gas supply unit 30 such that a first gas is supplied from the gas source 30a. Further, the controller 148 controls the flow rate controller 32b and the shut-off valve 32c of the gas supply unit 32 such that a nitrogen-containing gas is supplied from the gas source 32a. Further, the controller 148 controls the RF power source 224 of the plasma generation system to generate plasma of the nitrogen-containing gas. As a result, the process ST2 of the cycle C1 is performed while the wafer W passes through the region P2. Alternatively, in the process ST2, the controller 148 may control the heater unit 107 such that heat energy is supplied to the heater unit 107, instead of controlling plasma generation.

Next, the method MT will be evaluated with reference to Examples 1 and 2 and a Comparative Example. It should be understood that the following examples are provided for illustration only and do not limit the scope of the present disclosure.

In Examples 1 and 2, a titanium carbonitride film was formed on a silicon substrate by performing the cycle C1 of the method MT using the film formation apparatus 100. In addition, for formation of the titanium carbonitride film in Example 1, the optimized conditions for formation of a titanium nitride film were set as base conditions, and C₂H₄ gas was supplied at 30 sccm as a first gas. Further, for formation of the titanium carbonitride film in Example 2, C₂H₄ gas was supplied at 40 sccm as the first gas, unlike Example 1. Further, in the Comparative Example, a titanium nitride film was formed on a silicon substrate under the same conditions as those for formation of the titanium nitride film adopted as the base conditions in Examples 1 and 2.

Then, the work function of each of the titanium carbonitride films prepared in Examples 1 and 2 and the titanium nitride film prepared in Comparative Example was obtained through UV photoelectron spectroscopy. In addition, the composition (concentration of each element) of each of the titanium carbonitride films prepared in Examples 1 and 2 and the titanium nitride film prepared in Comparative Example was obtained through X-ray photoelectron spectroscopy. Results are shown in Table 1.

TABLE 1

| | Concentration (at. %) | | | |
|---|---|---|---|---|
| | Ti | N | C | W.F. (eV) |
| Comparative Example | 50.4 | 49.6 | | 3.8 |
| Example 1 | 48.0 | 37.6 | 13.7 | 3.9 |
| Example 2 | 47.4 | 35.5 | 16.5 | 4.1 |

As shown in Table 1, it was confirmed that the work functions of the titanium carbonitride films prepared in Examples 1 and 2 are higher than the work function of the titanium nitride film prepared in the Comparative Example. Further, it was confirmed that relatively large amounts of carbon could be introduced into the titanium carbonitride films in Examples 1 and 2.

While certain embodiments have been described, the present disclosure is not limited thereto and the embodiments described herein may be embodied in a variety of other forms. For example, the film formation apparatus applicable to the method MT may include any plasma source for exciting the nitrogen-containing gas and the first gas. Furthermore, the method MT may be performed using a single-substrate type film formation apparatus.

According to some embodiments of the present disclosure, it is possible to provide a titanium carbonitride film having a high work function and exhibiting high controllability with respect to carbon concentration.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of forming a titanium carbonitride film, comprising:
performing a cycle a plurality of times to form the titanium carbonitride film, the cycle including:
supplying a raw material gas of titanium into a process chamber in which a process object is accommodated, and
simultaneously supplying a first gas containing carbon and hydrogen and a second gas containing nitrogen into the process chamber.

2. The method of claim 1, further comprising:
performing a secondary cycle a plurality of times to form a titanium nitride film, before or after performing the cycle a plurality of times, the secondary cycle including:
supplying a raw material gas of titanium into the process chamber in which the process object is accommodated; and
supplying a third gas containing nitrogen into the process chamber.

3. The method of claim 2, wherein the secondary cycle is performed to form the titanium nitride film on a dielectric layer, followed by performing the cycle a plurality of times to form the titanium carbonitride film on the titanium nitride film.

4. The method of claim 2, wherein the third gas is NH₃ gas or triethylamine.

5. The method of claim 1, wherein the cycle performed a plurality of times further comprises, in each cycle, supplying a gas containing carbon and hydrogen into the process chamber between supplying the raw material gas of titanium into the process chamber and simultaneously supplying the first gas and the second gas into the process chamber.

6. The method of claim 1, wherein the first gas is hydrocarbon gas or triethylamine.

7. The method of claim 1, wherein the second gas is NH₃ gas or triethylamine.

8. The method of claim 1, wherein the raw material gas of titanium is TiCl₄ gas.

9. The method of claim 1, wherein, when simultaneously supplying the first gas and the second gas into the process chamber, plasma of the first gas and the second gas is generated in the process chamber.

10. A film formation apparatus comprising:
a process chamber;
a gas supply system supplying a raw material gas of titanium, a first gas containing carbon and hydrogen, and a second gas containing nitrogen into the process chamber; and
a controller controlling the gas supply system,
wherein the controller performs, a plurality of times, a control cycle for controlling the gas supply system to supply the raw material gas into the process chamber and controlling the gas supply system to simultaneously supply the first gas and the second gas into the process chamber.

11. The film formation apparatus of claim 10,
wherein the gas supply system further supplies a third gas containing nitrogen into the process chamber; and
wherein the controller performs a secondary control cycle for controlling the gas supply system to supply the raw material gas into the process chamber before or after performing the control cycle a plurality of times, and controlling the gas supply system to supply the third gas into the process chamber.

12. The film formation apparatus of claim 11, wherein the third gas is NH₃ gas or triethylamine.

13. The film formation apparatus of claim 10, wherein, in each control cycle performed a plurality of times, the controller controls the gas supply system to supply a gas containing carbon and hydrogen into the process chamber after controlling the gas supply system to supply the raw material gas into the process chamber, and before controlling the gas supply system to simultaneously supply the first gas and the second gas into the process chamber.

14. The film formation apparatus of claim 10, wherein the first gas is hydrocarbon gas or triethylamine.

15. The film formation apparatus of claim 10, wherein the second gas is NH₃ gas or triethylamine.

16. The film formation apparatus of claim 10, wherein the raw material gas of titanium is TiCl₄ gas.

17. The film formation apparatus of claim 10, further comprising:
a plasma generation system configured to excite a gas supplied into the process chamber,
wherein the controller controls the plasma generation system to excite the first gas and the second gas simultaneously supplied into the process chamber in the control cycle.
